(19) United States
(12) Patent Application Publication
(10) Pub. No.: US 2026/0243821 A1
(43) Pub. Date: Aug. 20, 2026

(54) PARALLEL CONTACTLESS TESTING OF INTERPOSERS AND SILICON BRIDGES

(71) Applicant: Advantest Corporation, Tokyo (JP)

(72) Inventors: Roland RÖSSLHUBER, Stuttgart (DE); Sarah ROTTACKER, Stuttgart (DE); Matthias SAUER, Böblingen (DE)

(21) Appl. No.: 19/324,001

(22) Filed: Sep. 9, 2025

Related U.S. Application Data
(60) Provisional application No. 63/758,918, filed on Feb. 14, 2025.

(51) Int. Cl. G01R 31/315; G01R 1/07; G01R 1/073

(52) U.S. Cl. CPC G01R 31/315; G01R 1/07; G01R 1/07328

(57) ABSTRACT

In various embodiments, a method for testing an interposer comprises moving, by automated test equipment, a first plurality of probes proximate to a first plurality of contacts of a device under test (DUT), where each of the first plurality of contacts is connected to one of a plurality of wires, moving a second plurality of probes proximate to a second plurality of contacts that are connected to one of the plurality of wires, driving the first plurality of probes with a plurality of first RF signals to induce a plurality of second RF signals in the plurality of wires, where the first plurality of probes move during the driving, measuring, via the plurality of second probes, at least one of the plurality of second RF signals, where the second plurality of probes move during the driving, and generating a test result based on the plurality of second RF signals.

### CROSS-REFERENCE TO RELATED APPLICATIONS

This application claims priority benefit of United States Provisional Patent Application titled, “PARALLEL CONTACTLESS TESTING OF INTERPOSERS AND SILICON BRIDGES,” filed on Feb. 14, 2025, and having Ser. No. 63/758,918. The subject matter of this related application is hereby incorporated herein by reference.

### BACKGROUND

### Field of the Various Embodiments

This application relates to systems and methods for reliable test tooling for packaged integrated circuits (IC) devices, and more specifically, to parallel contactless testing of interposers and silicon bridges.

### Description of the Related Art

Interposers and silicon bridges are typically used in various electronic assemblies to provide electrical interface routing between connections in a socket or on an integrated circuit. An interposer or silicon bridge includes various contact pads, such as solder balls or pins, with conductive traces and/or metallization between the contact pads that provide the interface routing.

Like other devices, interposers and silicon bridges need to be tested to determine that the conductive traces and/or metallization is making adequate connection between the appropriate contact pads and that there are no shorts, opens, or other flaws that might prevent the interposers and silicon bridges from operating correctly. In some cases, the interposers are tested after partial assembly, such as within an assembly of a high-performance computing (HPC) device. However, such testing is performed after a large portion of the assembly is fabricated and combined. Identifying failures in a partial assembly is more costly and time consuming. In other cases, various testing systems perform contact testing of interposers and silicon assemblies before adding the components to an electronic assembly. Testing such components in this manner reduces costs and time associated with identifying failed components. Other testing systems employ non-contact approaches, such as systems that rely on x-ray, e-beam, or other imaging approaches.

At least one drawback of testing systems is that such systems have difficulty efficiently testing interposers and silicon bridges. For example, various testing systems perform a test of a given wiring route within the interposer or silicon assembly by establishing physical contacts with contact pads that are connected via the conductive trace or metallization and measuring signals to detect failure conditions, such as a short or an open. The testing system sequentially performs tests for each route included in the interposer or silicon assembly. However, the contact pads for a given interposer might not be easily contactable during testing. The small sizes and pitches of a given contact pad can block attempts by the testing equipment to physically contact the contact pad being tested without physically contacting neighboring contact pads, which also increases the difficulty in manufacturing probe equipment or systems that include the dense concentration of small needles needed for contact. Contacting neighboring contact pads during tests degrades the measurements recorded by the testing system and causes the testing systems to generate false results. In addition, the contact pads might be damaged if physically contacted by a testing probe included in the testing system. Existing non-contact systems relying on imaging approaches require large and expensive testing apparatuses that are not compatible with typical semiconductor testing systems. Further, many conventional testing systems sequentially test and evaluate conductive leads or wires in a device such as an interposer, resulting in long testing times associated with testing every wire or conductive route in a DUT. Consequently, such testing systems greatly increase costs and time associated with testing complex electronic assemblies that include interposers or silicon bridges.

In view of the foregoing, what is needed in the art is an improved technique for testing interposers and silicon bridges.

### SUMMARY

In various embodiments, a computer-implemented method for testing an interposer or silicon bridge comprises moving, by automated test equipment, a first plurality of probes proximate to a first plurality of contacts of a device under test (DUT), where each contact of the first plurality of contacts is connected to a wire of a plurality of wires. The computer-implemented method also includes moving, by the automated test equipment, a second plurality of probes proximate to a second plurality of contacts of the DUT, where each contact of the second plurality of contacts is connected to a wire of the plurality of wires. The computer-implemented method further includes driving, by the automated test equipment, each probe of the first plurality of probes with one of a plurality of first RF signals to induce a plurality of second RF signals in the plurality of wires. The computer-implemented method further includes measuring, by the automated test equipment via the plurality of second probes, at least one RF signal of the plurality of second RF signals. The computer-implemented method further includes generating, by the automated test equipment, a test result based on at least the one RF signal of the plurality of second RF signals.

At least one technical advantage of the disclosed techniques relative to the prior art is that, with the disclosed techniques, interposers, silicon bridges, and other electronic equipment can be tested quickly and accurately using a parallel contactless approach without the need of bulky and costly imaging-based systems and/or other measurement techniques. In particular, the parallel contactless approach moves probes proximate to the DUT and performs parallel electrical tests that typically require sequential contact between a pair of contact points on the DUT and the testing system. In this manner, a testing system using the parallel contactless approach can acquire accurate results for multiple wires without damaging the DUT or introducing false measurements due to contact errors. The disclosed techniques also accurately identify faults, such as opens, shorts, and potential failures of neighboring wires, at greater speeds and at lower costs than conventional testing systems. Further, the disclosed techniques can identify functioning wires and faults with greater accuracy. These technical advantages provide one or more technological advancements over prior art approaches.

### BRIEF DESCRIPTION OF THE DRAWINGS

So that the manner in which the above recited features of the various embodiments can be understood in detail, a more particular description of the inventive concepts, briefly summarized above, can be had by reference to various embodiments, some of which are illustrated in the appended drawings. It is to be noted, however, that the appended drawings illustrate only typical embodiments of the inventive concepts and are therefore not to be considered limiting of scope in any way, and that there are other equally effective embodiments.

FIG. 1 illustrates a block diagram of a contactless testing system performing a test of a device under test (DUT), according to various embodiments.

FIG. 2 illustrates a conceptual diagram of the contactless testing system of FIG. 1 interacting with a DUT, according to various embodiments.

FIG. 3 illustrates example RF probes of the contactless testing system of FIG. 2 in proximity to the wire of the DUT, according to various embodiments.

FIG. 4 illustrates a testing arrangement for a plurality of contact pads of a DUT of FIG. 2, according to various embodiments.

FIG. 5 illustrates another testing arrangement for a plurality of contact pads of a DUT of FIG. 2, according to various embodiments.

FIG. 6 illustrates another testing arrangement for a plurality of contact pads of a DUT of FIG. 2, according to various embodiments.

FIG. 7 illustrates an arrangement of spectral graphs for a measurement RF signal received by the contactless testing system of FIG. 2, according to various embodiments.

FIG. 8 is a flow diagram of method steps for testing of a device under test, according to various embodiments.

### DETAILED DESCRIPTION

In the following description, numerous specific details are set forth to provide a more thorough understanding of the various embodiments. However, it will be apparent to one skilled in the art that the inventive concepts can be practiced without one or more of these specific details.

A contactless testing system disclosed herein enables interface routes of interposers and/or silicon bridges to be tested and evaluated in parallel without requiring contact with any leads, contact pads, solder balls, or pins of the interposers and/or silicon bridges. The contactless testing system includes a plurality of RF probes that are configured to establish capacitive couplings with contact leads of a DUT. The DUT can be a device that includes an interface under test (IUT), such as interface wiring. For example, the DUT can be an interposer or a silicon bridge that includes a wire or interface wiring as the IUT. During testing, a probe card connected to the RF probes responds to commands by moving the RF probes to a desired location and a desired position proximate to one or more target contact leads on the DUT. The probe card moves the RF probes along the x-axis, y-axis, and z-axis and can tilt the RF probes to modify orientations relative to the DUT. The movement is also relative to a prober moving a chuck that holds the DUT. A given RF probe includes a cable that can be extended to change the distance between the distal end of the RF probe and a target contact pad. Once at the target positions, each source RF probe couples (e.g., capacitively couples) with a corresponding first contact pad and each receiving RF probe couples with a corresponding second contact pad, each without making contact. The number of source RF probes do not need to match the number of receiving RF probes. For example, six source RF probes can couple with six contact pads that act as sources, and three receiving RF probes can couple with three contact pads that act as receptors. An RF tester generates one or more RF test signals (e.g., one or more carrier RF signals, modulated RF signals, s-parameters, etc.) at one or more selected frequencies. For a first set of RF test signals, each source RF probe induces a wire connected to the corresponding contact pad coupled to the source RF probe, to transmit an RF test signal. Each receiving RF probe receives a corresponding first measurement RF signal from a corresponding second contact pad. When the contactless testing system generates multiple RF test signals in parallel, a set of receiving RF probes collectively receive multiple measurement RF signals concurrently. The set of receiving RF probes transmit the multiple measurement RF signals to a testing module. The testing module analyzes the multiple measurement RF signals and identifies any test failures. The testing module provides one or more measurement RF signals, and the test results for evaluation of the device under test.

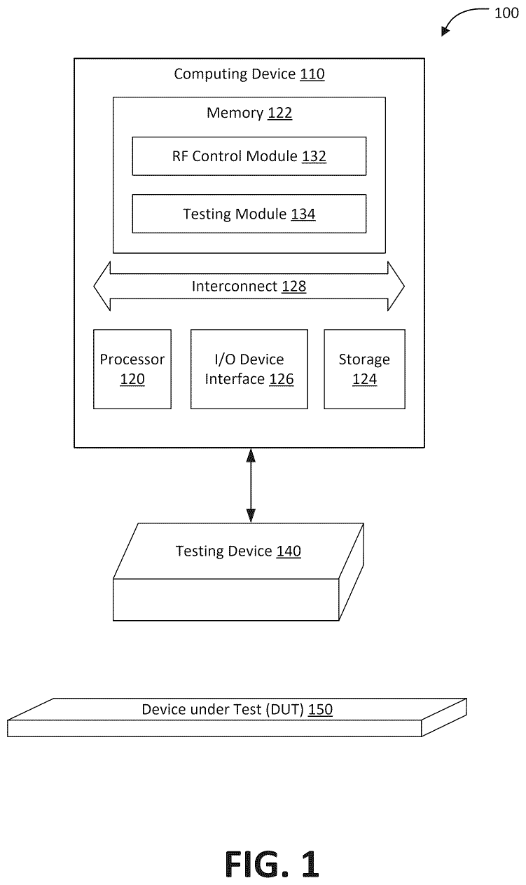

FIG. 1 illustrates a block diagram of a contactless testing system 100 performing a test of a device under test (DUT) 150, according to various embodiments. As shown, the contactless testing system 100 includes, without limitation, a computing device 110 and a testing device 140. The computing device 110 includes, without limitation, a processor 120, a memory 122, storage 124, an input/output (I/O) device interface 126, and an interconnect 128. The memory 122 includes, without limitation, a radio frequency (RF) control module 132 and a testing module 134.

In operation, the processor 120 executes instructions from the one or more modules 132, 134 stored in the memory 122 to control the testing device 140. In such instances, a given module 132, 134 can receive data from the testing device 140 and can transmit commands to the testing device 140 to control the operation of the testing device 140. Such operations include movement of the testing device 140 (e.g., a probe card, one or more probe carriers, one or more probes, etc.) and/or operation of one or more electrical tests on the DUT 150.

The computing device 110 is configured to implement one or more aspects of the various embodiments. In some examples, the computing device 110 individually controls one or more probes, probers, probe cards, testers, and/or other components of the contactless testing system 100. In various embodiments, the computing device 110, a controller device (not shown) that is included in the testing device 140, and/or other components (e.g., probes, cables, and connectors) of the testing device 140 can also work in concert to control the position and/or orientation of one or more probes included in the testing device 140 and control the flow of electricity, corresponding to testing RF signals, during electrical tests to test one or more components of the DUT 150. The computing device 110 is also configured to receive one or more measurement signals from the testing device 140, compare the one or more measurement signals to one or more predetermined and/or configurable thresholds and record a quality control result (e.g., pass, fail and/or the like) based on the comparison. Additionally, or alternatively, in some embodiments, the computing device 110 can perform other type of analysis, such as probabilistic analysis, complex modeling, and/or other post processing techniques to generate a result from the measurement signals transmitted from the testing device 140.

In some embodiments, the computing device 110 includes a processor 120, a memory 122, a storage 124, an I/O device interface 126, and an interconnect 128. The computing device 110 includes a desktop computer, a laptop computer, a smart phone, a personal digital assistant (PDA), tablet computer, or any other type of computing device configured to receive input, process data, and optionally display images, and is suitable for practicing one or more embodiments. The computing device 110 described herein is illustrative and any other technically feasible configurations that fall within the scope of the present disclosure.

The processor(s) 120 includes any suitable processor implemented as a central processing unit (CPU), a graphics processing unit (GPU), an application-specific integrated circuit (ASIC), a field programmable gate array (FPGA), an artificial intelligence (AI) accelerator, any other type of processor, or a combination of different processors, such as a CPU configured to operate in conjunction with a GPU. In general, the processor(s) 120 can be any technically feasible hardware unit capable of processing data and/or executing software applications. Further, in the context of this disclosure, the computing elements shown in the computing device 110 can correspond to a physical computing system (e.g., a system in a data center) or can be a virtual computing instance executing within a computing cloud.

The I/O device interface 126 enables communication of I/O devices with the processor(s) 120. The I/O device interface 126 generally includes the requisite logic for interpreting addresses corresponding to I/O devices that are generated by the processor(s) 120. I/O device interface 126 can also be configured to implement handshaking between the processor(s) 120 and the I/O devices, and/or generate interrupts associated with I/O devices. I/O device interface 126 can be implemented as any technically feasible CPU, ASIC, FPGA, any other type of processing unit or device. I/O devices include devices capable of providing input, such as a keyboard, a mouse, a touch-sensitive screen, a microphone, a remote control, a camera, and so forth, as well as devices capable of providing output, such as a display device. Additionally, I/O devices can include devices capable of both receiving input and providing output, such as a touchscreen, a universal serial bus (USB) port, and so forth. I/O devices can be configured to receive various types of input from an end-user of the computing device 110, and to also provide various types of output to the end-user of the computing device 110, such as displayed digital images or digital videos or text. In some embodiments, one or more of the I/O devices are configured to couple the computing device 110 to a network. A network includes any technically feasible type of communications network that allows data to be exchanged between the computing device 110 and external entities or devices, such as a web server or another networked computing device. For example, a network can include a wide area network (WAN), a local area network (LAN), a wireless (Wi-Fi) network, and/or the Internet, among others.

The memory 122 includes a random access memory (RAM) module, a flash memory unit, or any other type of memory unit or combination thereof. The processor(s) 120, the I/O device interface 126, and the network interface are configured to read data from and write data to the memory 122. The memory 122 includes various software programs that can be executed by the processor(s) 120 and application data associated with said software programs, including the RF control module 132 and the testing module 134 that performs individualized and/or group electrical tests on the DUT 150.

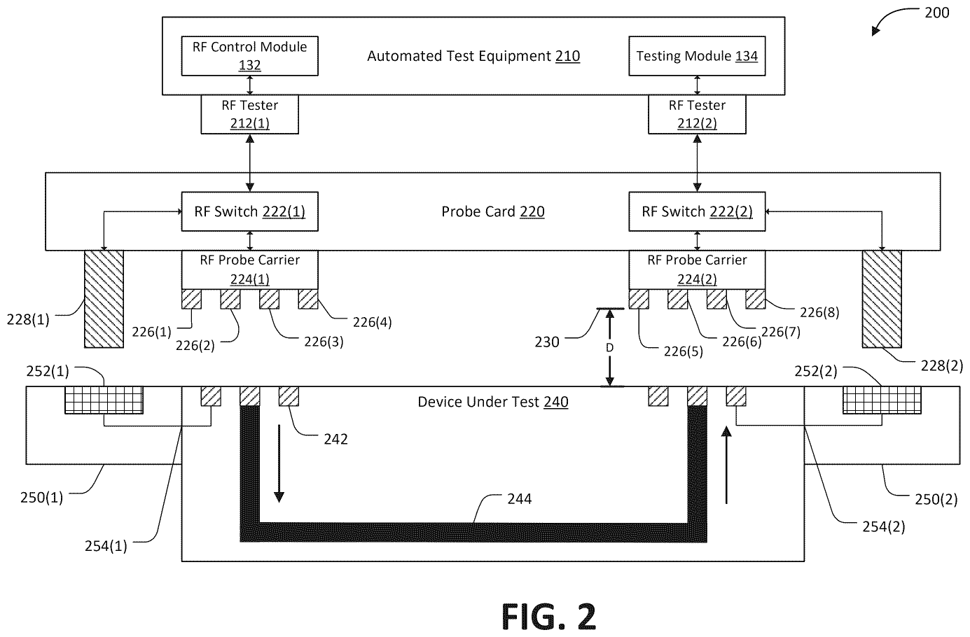

In various embodiments, the RF control module 132 included in the computing device controls one or more components of the testing device 140 and/or the computing device 110 when performing one or more electronic tests. As will be discussed in greater detail with respect to FIGS. 2-7, the RF control module 132 can control the positioning of one or more probes relative to the DUT 150 (e.g., controlling testing device 140 and/or a prober holding the DUT 150) and can drive the generation of a test RF signal. In some embodiments, positioning of the one or more probes relative to the DUT 150 uses any technically feasible actuators, such as one or more piezo actuators. Based on one or more capacitive couplings between the testing device 140 and the DUT 150, the test RF signal induces a corresponding RF signal in an IUT (e.g., interface wiring) included in the DUT 150. In some embodiments, the RF control module 132 can acquire data to determine the position of the probes. For example, the RF control module 132 can acquire image data (e.g., via a camera) and/or sensor data (e.g., laser measurements, sonic data, mechanical data, magnetic data) to determine the position of the probes along the x, y, and z axes, as well as determine an orientation (e.g., tilt relative to a plane of the testing device 140 and/or the DUT 150).

For example, the RF control module 132 can process the sensor data to determine the location and orientation of the probe. The RF control module 132 can then use the location and orientation to verify whether the probe is at a target distance that is proximate to the DUT 150 at the one or more contact pads. When the RF control module 132 determines that the probe 214 is not at the applicable position or orientation, the RF control module 132 can send one or more commands to the testing device 140 to adjust the position of the probe. In such instances, the RF control module 132 can iteratively process data acquired by the testing device 140 and generate commands to adjust the testing device 140 before completing verification and generating the test RF signal.

In various embodiments, the testing module 134 can include one or more types of components that perform various types of tests on the DUT 150. For example, the testing modules 134 can comprise a vector network analyzer (VNA) module, an electrical RF testing module, a circuit analysis module, and so forth. In such instances, one of the testing modules 134 can select a particular test to run (e.g., an S-parameter test, cluster analysis, outlier analysis, etc.) and the computing device 110 generates one or more commands to move the testing device 140 to a target location relative to the DUT 150. In various embodiments, the testing device 140 records signals detected from the DUT 150 and identifies insertion loss and return loss. For example, the testing module 134 can measure yields of RF signal characteristics, such as a waveforms, S-parameters, conductivity, resistance, signal characteristics (amplitude, phase, steepness of change, frequency spectrum, etc.), and so forth. Additionally, or alternatively, the testing device 140 can acquire the electrical measurements to enable the testing module 134 to identify test failures (e.g., shorts, opens, resonant frequencies, etc.). In such instances, the computing device 110 provides the electrical measurements and any test failures for evaluation of the DUT 150 via the I/O device interface 126.

Storage 124 includes non-volatile storage for applications and data, and can include fixed or removable disk drives, flash memory devices, and CD-ROM, DVD-ROM, Blu-Ray, HD-DVD, or other magnetic, optical, or solid state storage devices. The storage 124 can be a disk drive storage device. Although shown as a single unit, the storage 124 can be a combination of fixed and/or removable storage devices, such as fixed disc drives, floppy disc drives, tape drives, removable memory cards, or optical storage, network attached storage (NAS), or a storage area-network (SAN). Software programs, including one or more testing applications that perform individualized and/or group tests can be stored in storage 124 and loaded into memory 122 when executed.

The interconnect 128 is inclusive of any technically feasible internal and/or external data busses, memory busses, system busses, expansion busses and/or the like. The interconnect 128 includes a collection of electrical pathways that allows data, addresses, and control signals to be transferred between the various components of the computing device 110 and/or external devices and components. While discussed in the singular for clarity, the interconnect 128 is illustrative of one or more interconnects 128 that connect, for example, the processor 120 to the memory 122 and/or the storage 124, connects the computing device 110 to other devices including the testing device 140, I/O devices, peripheral devices, other computing devices, and/or the like. In some embodiments, the interconnect 128 includes PCI Express (PCIe) connections for high-speed internal connections and Universal Serial Bus (USB) connections for connecting external devices.

The DUT 150 can be one of various types of electronic components. for example, the DUT 150 can be an interposer, a silicon bridge, a silicon interposer (SIP), an embedded multi-die interconnect bridge (EMIB), a local silicon interconnect (LSI), etc. In various embodiments, the DUT 150 includes one or more interfaces under test (IUT) (not shown). In such instances, the contactless testing system 100 can test one or more IUTs by positioning the testing device 140 to couple with the applicable connected pair of contact pads on the DUT 150. For example, the contactless testing system 100 can test a plurality of IUTs in parallel by positioning a probe such that multiple probes couple with respective contact pads simultaneously. In such instances, the contactless testing system 100 can generate a plurality of test RF signals in parallel to induce different currents in different IUTs.

FIG. 2 illustrates a conceptual diagram of the contactless testing system 100 of FIG. 1 interacting with a DUT 240, according to various embodiments. As shown, the contactless testing system 200 includes, without limitation, automated testing equipment (ATE) 210, a probe card 220, and a testing interface 250. The DUT 240 includes, without limitation, a plurality of contact pads 242, and a plurality of wires 244. The automated testing equipment 210, includes, without limitation, the RF control module 132, the testing module 134, and one or more optional RF testers 212. The probe card 220 includes, without limitation, one or more optional RF switches 222, one or more RF probe carriers 224, one or more RF probes 226, and one or more optional contact probes 228. The testing interface 250 includes, without limitation, one or more optional large contact pads 252 and one or more optional connection lines 254.

In various embodiments, the DUT 240 could be an interposer that includes a plurality of wires 244 that are to be tested. In such instances, the automated test equipment 210 is configured to use the probe card 220 to test the IUTs included in the DUT 240. In some embodiments, the DUT includes one or more signal lines or transmission lines. In such instances, the automated test equipment 210 can test the signal lines and/or transmission lines as additional “wires” for testing. Before initiating a test, the RF control module 132 transmits commands to the probe card 220. The commands include a command for the RF switch 222 to select an RF probe carrier (e.g., the RF probe carrier 224(1)) and one or more RF probes 226 (e.g., RF probes 226(1)-226(4)) to act as sources, and select another RF probe carrier (e.g., the RF probe carrier 224(2)) and one or more RF probes 226 (e.g., RF probes 226(5)-226(8)) to act as receptors. The RF control module 132 transmits commands to move the selected RF probe carriers 224 and/or the selected RF probes 226 to target positions and/or target orientations relative to target contact pads 242 on the DUT 240. When at the target positions, a source RF probe 226 (e.g., the RF probe 226(2)) in the source RF probe carrier 224(1) is coupled to the target contact pad 242 via capacitive coupling. One of the RF control module 132 or the testing module 134 drives the source RF tester 212 (e.g., the RF tester 212(1)) to generate a test RF signal. Due to the coupling between the source RF probe 226 and the contact pad 242, the source RF probe 226(2) induces a current in IUT (e.g., the wire 244). A receiving RF probe 226 (e.g., the RF probe 226(6)) of the receiving RF probe carrier 224(2) receives a measurement RF signal corresponding to the current in the wire 244. The receiving RF probe carrier 224 transmits the measurement RF signal to the testing module 134 via the receiving RF tester 212(2). The testing module 134 analyzes the measurement RF signal to identify any failures associated with the wire 244 and determines whether the DUT 240 is faulty.

In various embodiments, the RF control module 132 selects a plurality of wires 244 to test in parallel. In such instances, the RF control module 132, selects a plurality of contact pads 242 for coupling and the RF switches 222 selects a plurality of RF probes 226(1)-226(8) from the plurality of RF probe carriers 224 to couple with the selected plurality of contact pads 242. In some embodiments, the RF switch 222(1) for the source RF probe carrier 224(1) acts as stimulus splitter, switch, or combination splitter and switch (“splitch”) that can split a given RF signal into multiple ports. In such instances, use of the RF switch 222(1) as a splitter increases the parallelism of testing by using the same test RF signal for multiple contact pads in different locations of the DUT 240. Additionally, or alternatively, in some embodiments, the RF switch 222(2) for the receiving RF probe carrier 224(2) can be a measurement combiner or switch that combines the measurement RF signals received from multiple contact pads 242 into a single measurement unit. In such instances, use of the RF switch 222(2) as a combiner increases the parallelism and efficiency by combining measurement RF signals from a plurality of contact pad 242 into a single measurement value that is representative of a pass or fail. In some embodiments, the RF switch 222(1) is included in the probe card 220. Alternatively, in some embodiments, the RF switch 222(1) is included in the ATE 210.

In various embodiments, the RF control module 132 verifies that the probe distance 230 (“D”) between a given RF probe 226 and the target contact pad 242 is within a threshold range (e.g., 1 to 10 μm) to enable capacitive coupling and reductions in distance-based signal loss. In such instances, the RF control module 132 can acquire and process image data (e.g., via a camera) and/or other types of sensor data (e.g., laser measurements, sonic data, mechanical data, magnetic data, etc.) to determine the position of the RF probe 226 and generate commands to move the RF probe 226 within the threshold range. In some embodiments, the RF probe carrier 224 can include one or more distance sensors to aid the RF control module 132 to determine the probe distance 230 and/or a tilt of the RF probe 226 relative to the plane of the DUT 240. Additionally, or alternatively, in some embodiments, the contactless testing system 200 operates in a continuous mode, where one or more of the RF probes 226 are in motion while coupled with the contact pad 242. In such instances, the RF probe 226 can induce the target RF signal and/or acquire the measurement RF signal while moving from the target contact pad 242 to a different contact pad.

In various embodiments, the RF probe carrier 224 can direct a beam of the test RF signal to the target contact pad 242. Additionally, or alternatively, the RF control module 132 can control the RF probe carrier 224 to use various beamforming methods to couple parallel probes 226 with parallel contact pads 242. In such instances, the RF control module 132 can parallelize the coupling of the RF probe carrier 224 to a plurality of contact pads 242 and can drive the RF tester 212 to generate multiple test RF signals (e.g., a distinct test RF signal for each contact pad 242 coupled to the RF probe carrier 224). In this manner, the contactless testing system 200 can test multiple wires 244 in parallel by receiving multiple measurement RF signals in parallel and identifying any failures.

In some embodiments, the DUT 240 connects to the testing interface 250. For example, one of the contact pads 242 can connect to a large contact pad 252(1) (e.g., a testing contact) via a connection line 254(1). In such instances, the probe card can electrically couple to the contact pad 242 included in the DUT 240 when the contact probe 228(1) physically contacts the large contact pad 252(1). In this manner, the testing interface 250 can aid in testing the DUT 240 for certain failure modes (e.g., shorts with a ground signal).

In various embodiments, the testing module 134 receives one or more measurement RF signals from the receiving RF probe carrier 224(2) and analyzes the measurement RF signals to identify potential failure conditions. Such failure conditions include full defects, such as an open condition (e.g., loss of connectivity due to non-conductance) and/or a short condition (e.g., extra connectivity due to unwanted conductance). The failure conditions can also include partial defects, such as a resistive open condition (e.g., partial loss) and/or a resistive short (e.g., partial extra connectivity). Such conditions can also be associated with connections to a specific line, such as a short to a ground signal, an unwanted open to a power distribution line, and/or an unwanted short to the power distribution line. In various embodiments, the testing module 134 identifies the DUT 240 as faulty upon identifying at least one failure condition in any IUT included in the DUT 240. Alternatively, the testing module 134 can identify a potential failure condition for a given IUT (e.g., the wire 244) and flag the analysis for further review. Additionally, or alternatively, the testing module 134 can deduce a cause for the failure, such as a spatial pattern to identify which wires 244 failed, a strength indication to determine the number of full defects compared to resistive defects, and/or any differences in symmetry of results. In some embodiments, an edge processing device and/or a cloud-based processing device can analyze the one or more measurement RF signals to generate the test results.

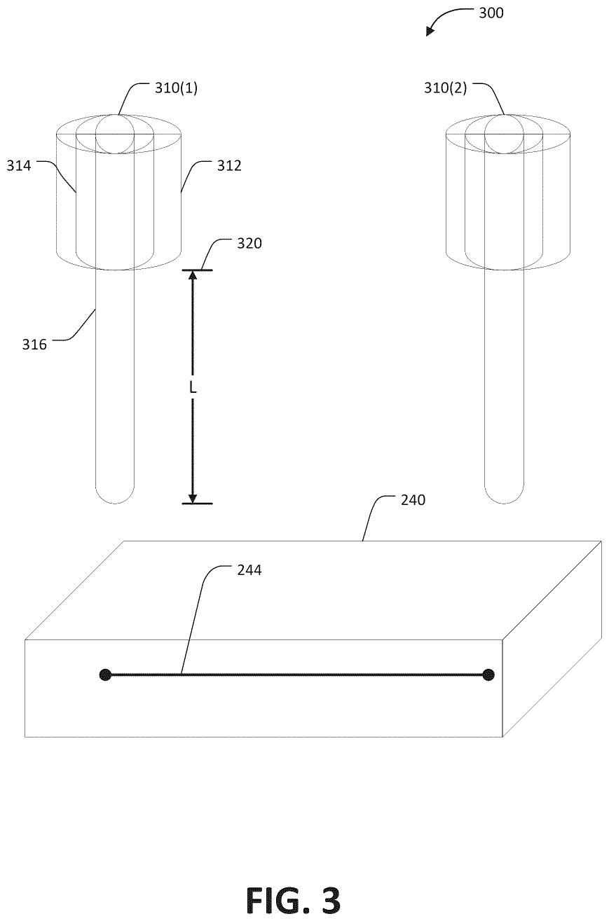

FIG. 3 illustrates example RF probes 226 of the contactless testing system 200 of FIG. 2 in proximity to the wire 244 of the DUT 240, according to various embodiments. As shown, the configuration 300 includes RF probe portions 310 (e.g., a portion of the RF probe carrier 224 and/or the RF probe 226) and the DUT 240. The RF probe portion 310 includes, without limitation, an outer isolation layer 312, an inner isolation layer 314, and an inner probe 316.

In various embodiments, the RF probe portion 310 comprises a portion of the RF probe carrier 224 that includes the RF probe 226 (e.g., a contactless probe 226). The contactless probe includes one or more isolation layers (e.g., isolation layers 312, 314). The isolation layers 312, 314 are configured to provide shielding and/or protection between the contactless probe 226 and the DUT 240. For example, one or more of the isolation layers 312, 314 can include a non-conductive and/or RF shielding material (e.g., silicon nitride) that improves the capacitive coupling between the contactless probe 226 and the DUT 240. The isolation layers 312, 314 can also include one or more shielding layers to minimize crosstalk between RF probes 226 and/or contact pads 242.

In various embodiments, the inner probe 316 is a portion of the contactless probe 226 that comprises an extendible wire or cable (e.g., a coaxial cable) that can extend a length 320 relative to the end of the inner isolation layer 314. In some embodiments, the RF probe carrier 224 causes the contactless probe 226 to extend the inner probe 316. Extension of the inner probe 316 improves the sensitivity of the contactless probe 226 and raises the signal strength of the test RF signal. In such instances, the increased signal strength of the test RF signal increases the likelihood of inducing a current in the wire 244 and/or increases the signal strength of the measurement RF signal measured from the wire 244.

Additionally, or alternatively, in some embodiments, the RF probe portion 310 can move to contact the DUT 240 when establishing a capacitive coupling with a contact pad 242 of the DUT 240. In such instances, the RF probe portion 310 contacts the DUT 240 using a small amount of force (e.g., a “soft touch”) such that the physical connection does not damage the DUT 240. This physical contact contrasts with the physical contact necessary for a direct electrical connection, as more force is needed to form a reliable electrical circuit between the RF probe portion 310 and the DUT 240. In some embodiments, the RF probe portion 310 and/or the contactless testing system 200 includes components to enable the physical connection, such as a spring layer, one or more buckling mechanisms (e.g., needles), a sense unit and/or a physical connection to a sense unit, and/or other components that detect physical attributes (e.g., force detection, capacitive detection, conductive detection, etc.) to detect when the RF probe portion 310 is physically contacting the DUT 240. In such instances, the RF probe carrier 224 can move the RF probe portion 310 away from the DUT 240 such that a probe distance 230 is formed between the end of the RF probe portion 310 and the surface of the DUT 240. In this manner, the probe distance 230 is lowered, improving the signal strength between the RF probe portion 310 and the wire under test.

In various embodiments, the inner probe 316 couples with the wire 244 included in the DUT 240 to form a signal path. When the RF tester 212 generates the test RF signal, the test RF signal can have a high frequency (e.g., 5-20 GHz) such that the signal characteristics of the test RF signal change based on the length of the signal path. To modify the operation of the signal path, the inner probe 316 can extend from the inner isolation layer 314 to modify the length of the signal path and/or modify the probe distance 230 between the distal end of the inner probe 316 and the target contact pad 242 at the end of the wire 244. For example, the test RF signal may include one or more resonant frequencies that are at least based on the length of the signal path. In such instances, the RF control module 132 can determine a target length of the signal path and cause the length 320 of the inner probe 316 to be adjusted to adjust the length of the signal path to approximately match the target length.

The RF probes 226 including the probe portions 310 are one example of probes that can be included in the contactless testing system 100. In various embodiments, the contactless testing system 100 can include other topologies that include other types of probes in addition to, or in lieu of, the RF probes 226 that include the probe portions 310. For example, the contactless testing system 100 can include probes that include various types of conductors, such as coaxial, transverse electromagnetic (TEM), and/or quasi-TEM interfaces. Additionally, or alternatively, in various embodiments, the end of the conductor can be cut, where the open surface of the conductor is exposed to the DUT 240. In such instances, the probe does not contact the DUT 240 and enables coupling with the DUT 240.

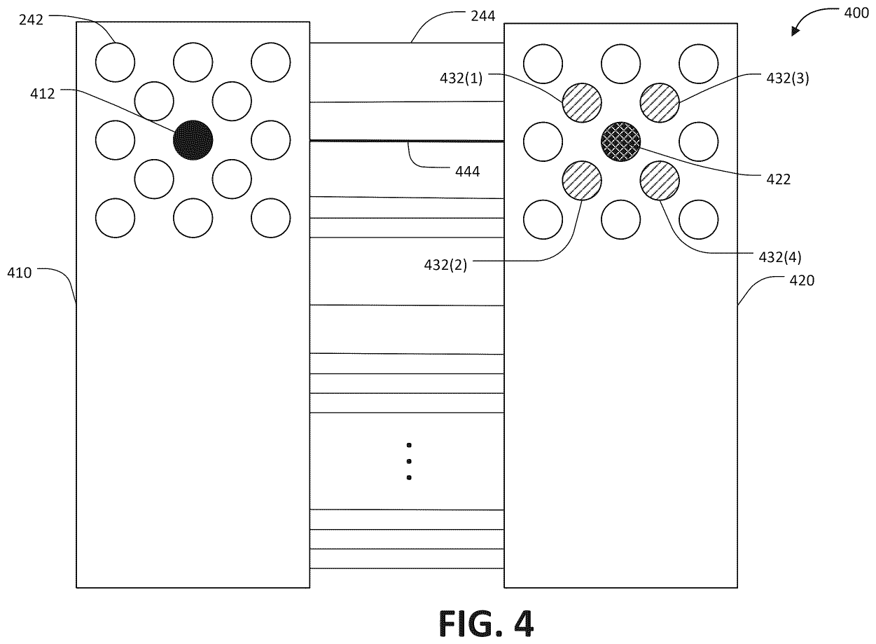

FIG. 4 illustrates a testing arrangement for a plurality of contact pads 242 of a DUT 240 of FIG. 2, according to various embodiments. As shown, the testing arrangement 400 includes, without limitation, a first interface 410, a second interface 420, a plurality of wires 244, and a wire under test (WUT) 444. The first interface 410 includes, without limitation, a plurality of contact pads 242. The plurality of contact pads 242 includes, without limitation, a source contact pad 412. The second interface 420 includes, without limitation, a plurality of contact pads 242. The plurality of contact pads 242 includes, without limitation, a receiving contact pad 422 and a plurality of neighboring contact pads 432.

In various embodiments, the interfaces 410, 420 are portions of a common interposer or bridge. The contactless testing system 200 can test each of the plurality of wires 244 by identifying the pairs of contact pads 242 on each end of an IUT, such as the WUT 444, and performing electrical tests. For example, the WUT 444 includes the source contact pad 412 on a first end and a receiving contact pad 422 on a second end.

In operation, the contactless testing system 200 can couple to multiple contact pads 242 when performing tests associated with the WUT 444. For example, multiple RF probes 226(5)-226(8) of the receiving RF probe carrier 224(2) can couple with the receiving contact pad 422 and the neighboring contact pads 432 (e.g., 432(1)-432(4)), respectively. The source RF probe carrier 224(1) induces a current in the WUT 444 due to a coupling between the source contact pad 412 and an RF probe 226(1) on the source RF probe carrier 224(1). The receiving RF probe carrier 224(2) can measure a measurement RF signal that can include signals at one or more frequencies that correspond to a current transmitted by the WUT 444 and/or currents transmitted by one or more neighboring wires 244 that are connected to neighboring contact pads 432(1)-432(4). In such instances, a measurement RF signal that includes energy for the frequency of current carried on the WUT 444 below a threshold indicates a failure condition of open or resistive open. Further, a measurement RF signal that includes energy for frequencies of current carried on the neighboring wires 244 above a threshold indicate a failure condition of short or resistive short. In some embodiments, the design of the WUT 444 can cause the measured frequencies to indicate other conditions. For example, a measurement RF signal that includes energy for the frequency of current carried on the WUT 444 below a threshold indicates a failure condition of a short to ground.

In various embodiments, the contactless testing system 200 can perform a testing sweep of the plurality of contact pads 242 by successively selecting the source and receiving contact pads 412, 422. For each receiving contact pad 422, the receiving RF probe carrier 224(2) couples to one or more neighboring contact pads 432 and tests for failure conditions. In this manner, the contactless testing system 200 can test for multiple failure conditions and accurately identify failure and failure conditions for any of the plurality of wires 244. For example, the testing module 134 can identify one or more full shorts and/or resistive shorts based on analyzing the spectral energy included in a given measurement RF signal.

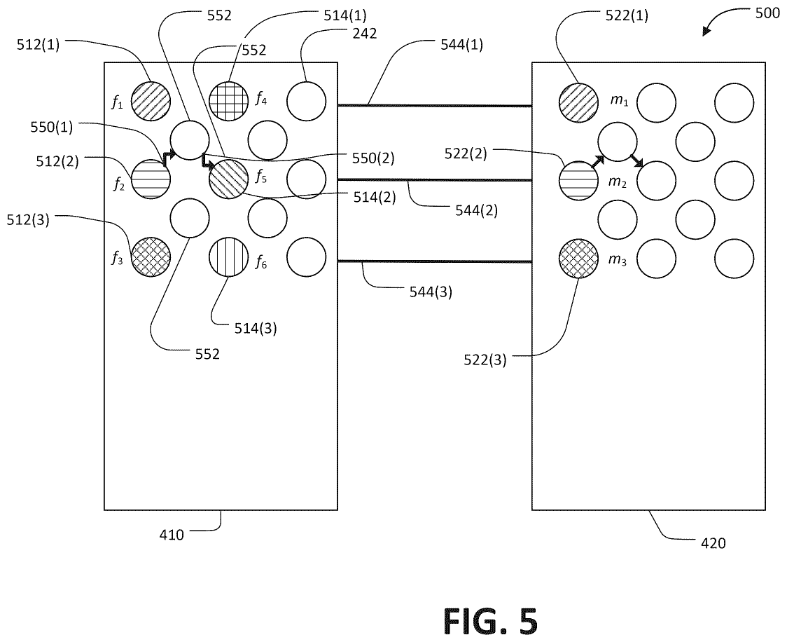

FIG. 5 illustrates another testing arrangement for a plurality of contact pads 242 of a DUT 240 of FIG. 2, according to various embodiments. As shown, the testing arrangement 500 includes, without limitation, the first interface 410, the second interface 420, and a plurality of wires under test (WUT) 544. The first interface 410 includes, without limitation, a plurality of contact pads 242 that includes, without limitation, a first plurality of testing contact pads 512, a second plurality of contact pads 514, and an intermediate column of contact pads 552. The second interface 420 includes, without limitation, a plurality of contact pads 242 that includes, without limitation, a plurality of receiving contact pads 522.

In operation, the source RF probe carrier 224(1) provides a plurality of test RF signals with different RF characteristics (e.g., RF frequencies f₁-f₆). The test RF signals include distinct RF signals (e.g., f₁-f₃) for each WUT 544 (e.g., 544(1)-544(3)), as well as one or more additional test RF signals (e.g., f₄-f₆) that are used to detect potential failures associated with neighboring wires. During testing of the group of WUTs 544(1)-544(3), multiple RF probes 226(1)-226(3) of the source RF probe carrier 224(1) can couple with the first plurality of testing contact pads 512(1)-512(3) and a second plurality of contact pads 514(1)-514(3). In such instances, the contactless testing system 200 can include multiple source RF probes carriers 224(1) and/or include additional RF probes 226 on the source RF probe carriers 224(1). The receiving RF probes 226(5)-226(7) of the receiving RF probe carrier 224(2) receives the plurality of measurement signals m₁-m₃.

When a given WUT 444(1) is operating properly, the corresponding measurement RF signal includes spectral energy corresponding to the spectral energy of the corresponding test RF signal and minimal spectral energies of the other RF signals. For example, the testing module 134 can classify WUT 544(1) as passing when the measurement RF signal m₁ includes at least a threshold amplitude of spectral energy corresponding to frequency f₁ and minimal spectral energy corresponding to the frequencies f₂-f₆. In contrast, the testing module 134 can classify the WUT 544(2) as failing when the measurement RF signal m₂ includes both a threshold amplitude of spectral energy corresponding to the frequency f₂ and spectral energy for at least one of the other frequencies f₁, f₃-f₆ that exceeds a minimal threshold, indicating a short condition due to measuring spectral energy from current traversing along a neighboring wire 544 (e.g., 544(1), 544(3)). Similarly, the testing module 134 can classify the WUT 544(3) as failing when the measurement RF signal m₃ includes an amplitude of spectral energy corresponding to the frequency f₃ below a threshold, indicating an open condition. In some embodiments, the design of the WUT 544(3) can cause the measured frequencies to indicate other conditions. For example, the testing module 134 can classify the WUT 544(3) as failing when the measurement RF signal m₃ includes an amplitude of spectral energy corresponding to the frequency f₃ below a threshold, indicating a short to ground.

In various embodiments, the number of testing frequencies generated by the contactless testing system is based on the test being performed. For example, when performing a pass/fail test, the testing RF frequency used for the WUT 544 is distinguishable from the frequencies used for neighboring wires. In such instances, the RF testing module 134 can generate a pair of test RF signals, a first test RF signal for the WUT 544, and a second test RF signal for a plurality of neighboring wires. Additionally, or alternatively, in various embodiments, the contactless testing system 200 can use one or more splitters and/or combiners to parallelize the testing of multiple WUTs 544 at different locations of the interfaces 410, 420 where the likelihood of a short or another defect related to the respective WUTs 544 is minimal.

In some embodiments, the contactless testing system 200 performs testing in a piecewise configuration. In such instances, the RF probes carriers 224 and/or the RF probes 226 continually stop over a set of contact pads 242 on the interfaces 410, 420 to inject test RF signals, acquire the measurement RF signals, and/or analyze the measurement RF signals before moving to a different set of contact pads. For example, the contactless testing system 200 can sweep through testing of the plurality of contact pads 242, as indicated by scanning direction 550 (e.g., arrows 550(1)-550(2)). For example, upon acquiring measurement RF signals for a first plurality of WUTs 544(1)-544(3) using the first plurality of testing contact pads 512, the RF control module 132 can then cause the probe card 220 and/or the RF probes carriers 224 to move along the scanning direction 550(1). The probe card 220 and/or the RF probe carriers 222 cause the RF probes 226 to stop and test a next plurality of WUTs 544 (not shown) by coupling with the intermediate column of contact pads 552. Upon acquiring measurement RF signals for the next plurality of WUTs 544, the RF control module 132 can the cause the probe card 220 and/or RF probe carriers 224 to continue along the scanning direction 550(2) to test another plurality of WUTs 544 (not shown) by coupling with the next column of contact pads, which corresponds to the second plurality of contact pads 514. In this manner, the contactless testing system 200 can perform tests on each wire included in the DUT 240 using a configurable set of testing RF signals.

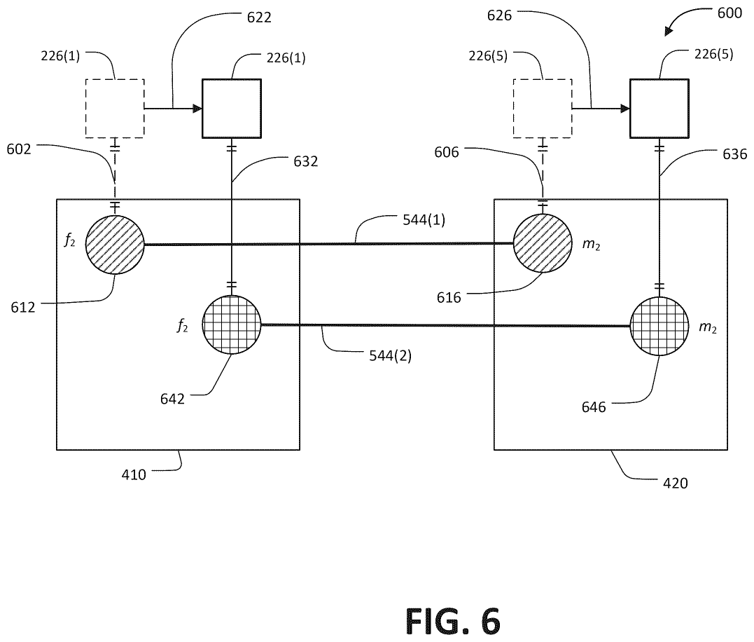

FIG. 6 illustrates another testing arrangement for a plurality of contact pads of a DUT of FIG. 2, according to various embodiments. As shown, the testing arrangement 500 includes, without limitation, a source RF probe 226(1), a receiving RF probe 226(5), the first interface 410, the second interface 420, and a plurality of wires under test (WUT) 544. The first interface 410 includes, without limitation, a first testing contact pad 612 and a second testing contact pad 642. The second interface 420 includes, without limitation, first receiving contact pad 616 and a second receiving contact pad 646.

In operation, the contactless testing system 200 performs testing in a continuous configuration. In such instances, the RF probe carriers 224 and/or the RF probes 226 continually move over different contact pads 242 of the interfaces 410, 420 to inject one or more test RF signals while the acquiring, transmitting, and/or analyzing the measurement RF signals. Alternatively, in some embodiments, the contactless testing system 200 performs stepwise measurements, such as injecting the test RF signals into a first group of contact pads 242, measuring, and analyzing the corresponding measurement RF signals before moving the RF probe carriers 224 and/or the RF probes 226 to another group of contact pads 242. In such instances, the time expended to test a given DUT 240 increases due to an index time associated with the movement between groups of contact pads 242.

When performing testing in the continuous configuration, one or more of the source RF probe 226(1) and the receiving RF probe 226(5) can initially couple with a first set of contact pads. For example, the source RF probe 226(1) can initially form a coupling 602 with the first testing contact pad 612. and the receiving RF probe 226(5) can initially form a coupling 606 with the first receiving contact pad 616. In various embodiments, the source RF probe 226(1) traverses in the scanning direction 622 and the receiving RF probe 226(5) traverses in the scanning direction 626. In some embodiments, the scanning directions 622, 626 can differ based on the configuration of the contact pads 612, 616, 642, 646 and/or the WUTs 544.

When the RF probes 226(1), 226(5) traverse along the respective scanning directions 622, 626, the contactless testing system 200 tests the WUT 544(1) using the couplings 602, 606. The source RF probe 226(1) injects a test RF signal into the WUT 544(1) via the first testing contact pad 612, and the receiving RF probe 226(5) acquires a measurement RF signal via the first receiving contact pad 616. Due to the movement of the RF probes 226(1), 226(5), the RF probes 226(1), 226(5) break the couplings 602, 606 and form new couplings. The source RF probe 226(1) forms a coupling 632 with the second testing contact pad 642 and the receiving RF probe 226(5) forms a coupling 636 with the second receiving contact pad 646. Upon establishing the couplings 632, 636, the contactless testing system 200 can test the WUT 544(2) while the RF probes 226(1), 226(5) continue to traverse along the scanning directions 622, 626.

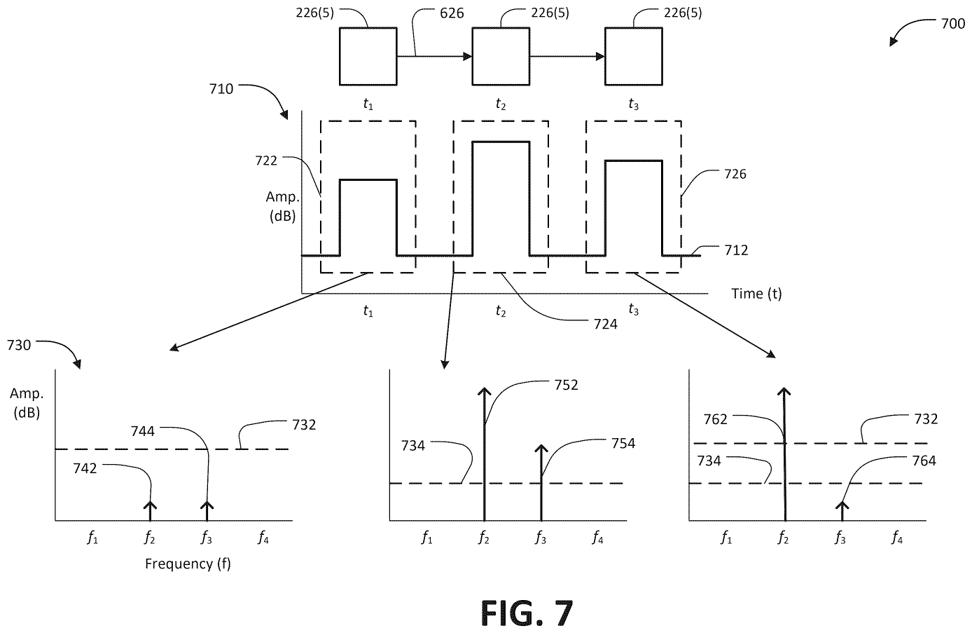

FIG. 7 illustrates an arrangement 700 of spectral graphs for a measurement RF signal received by the contactless testing system 200 of FIG. 2, according to various embodiments. As shown, the time series graph 710 includes, without limitation, a time-series signal 712 received by the receiving RF probe 226(5) while traversing the scanning direction 626, and segments 722, 724, 726. The frequency spectrum graphs 730 include, without limitation, an expected amplitude threshold 732, an unexpected amplitude threshold 734, and spectral energies 742-766 at one or more frequencies included in the measurement RF signal 712.

In various embodiments, the testing module 134 receives a measurement RF signal (e.g., m₂) that is received at a given receiving contact pad (e.g., the receiving contact pad 646) over a specific time period. Additionally, or alternatively, in some embodiments, the testing module 134 receives the measurement RF signal as a time series signal received via two or more receiving contact pads over distinct time periods. For example, the receiving RF probe 226(5) can acquire the measurement RF signal 712 as the receiving RF probe 226(5) traverses along the scanning direction 626. In such instances, portions of the measurement RF signal 712 can correspond to acquiring the measurement RF signal 712 while coupled to different contact pads 242 at different time periods. Following the above example, the receiving RF probe 226(5) can acquire the first segment 722 of the measurement RF probe 226(5) while coupled with the first receiving contact pad 616 during time period t₁. In some embodiments, the receiving RF probe 226(5) can acquire the first segment 722 of the measurement RF probe 226(5) while stationary. Alternatively, the receiving RF probe 226(5) can acquire the first segment 722 of the measurement RF probe 226(5) while in motion (e.g., traversing along the scanning direction 626 during the time period t₁). The receiving RF probe 226(5) can the acquire the second segment 724 of the measurement RF probe 712 while coupled with the second receiving contact pad 646 and can the acquire the third segment 726 of the measurement RF probe 712 while coupled with a third receiving contact pad WUT 544(3).

In various embodiments, the testing module 134 uses a Fast Fourier Transform (FFT) to convert one or more segments 722-726 of the measurement RF signal 712 from the time domain into the frequency domain. In some embodiments, the testing module 134 can perform other algorithms known to one of skill in the art to determine a frequency spectrum. Following the above example, the testing module 134 generates one or more frequency spectrum graphs 730 corresponding to the segment 722 of the measurement RF signal 712 to analyze the spectral energy of the measurement RF signal 712 when the receiving RF probe 226(5) was coupled to the first receiving contact pad 616 and was testing the WUT 544(1). In this manner, the testing module 134 can perform various tests on the WUT 544(1) by analyzing the segment 722 of the measurement RF signal 712. In various embodiments, the testing module 134 analyzes the frequencies included in the segment 722 of the measurement RF signal 712. As shown, the peaks 742, 744 in the frequency spectral graph correspond to the frequency spectra of the measurement RF signal 712. The frequency spectrum graph thus indicates whether the segment 722 of the measurement RF signal 712 includes spectral energy from the expected test RF signal (e.g. f₂) and/or spectral energy from one or more other test RF signals (e.g., f₁, f₃-f₇).

As shown, the frequency spectrum graph 730 for the first segment 722 includes a first peak 742 at the frequency f₂ and a second peak 744 at the frequency f₃. Because the peak 742 is below the expected amplitude threshold 732, the respective peaks 742, 744 indicate an open condition for the WUT 544(1) due to the measurement RF signal 712 not carrying a significant amount of a current that was induced by the test RF signal f₂ in the WUT 544(1). Similarly, the frequency spectrum graph 730 for the second segment 724 includes a first peak 752 at the frequency f₂ and a second peak 754 at the frequency f₃. Because peak 754 is above the unexpected amplitude threshold 734, the frequency spectrum graph 730 indicates a short condition for the WUT 544(2) due to the measurement RF signal 712 including a significant current from a current that was induced by the test RF signal f₃ in a neighboring wire.

In contrast, the frequency spectrum graph 730 for the third segment 726 includes a first peak 762 at the frequency f₂ and a second peak 764 at the frequency f₃. As the peak 762 is above the expected amplitude threshold 732 and the peak 764 is below the unexpected amplitude threshold 734, the frequency spectrum graph 730 indicates a target operation condition. The target operation condition includes the measurement RF signal 712 carrying significant amount of a current that was induced by the test RF signal f₂ in the WUT 544(3) and does not include significant current from a current that was induced by the test RF signal f₃ in a neighboring wire

In various embodiments, the testing module 134 can perform various types of analysis based on the measurement RF signal 712. For example, the testing module 134 can identify the frequencies used to indicate the open condition and/or the short condition to identify the applicable wires 244 that caused the open condition and/or the short condition. Other types of analysis, such as cross-comparison and aggregation, can be performed by the testing module 134 based on the measurement RF signal 712 and/or the graphs 710, 730. The testing module 134 can perform various tests based on measurements acquired to identify one or more RF signal characteristics (e.g., captured waveforms, modulated signals, S-parameters, conductivity, resistance, signal amplitude, signal phase, steepness of change, frequency spectrum). Other types of diagnostic testing and/or pass/fail testing can be performed. For example, the testing module 134 can identify, without limitation differences in symmetry, defect strength (e.g., resistive defects compared to full defects), and/or failure patterns. The testing module 134 can also use algorithms to make pass/fail judgments, such as using static thresholds, dynamic threshold, cluster analysis, outlier analysis, neural networks, etc.

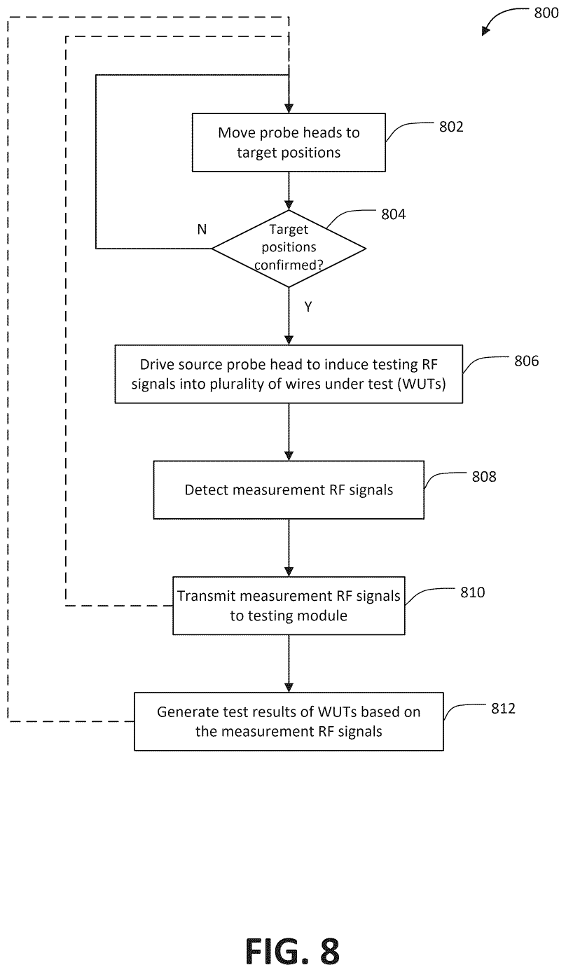

FIG. 8 is a flow diagram of method steps for testing of a device under test, according to various embodiments. Although the method steps are described in conjunction with the embodiments of FIGS. 1-7, persons of ordinary skill in the art will understand that any system configured to perform the method steps, in any order, is within the scope of the invention.

As shown, a method 800 begins at step 802, where a contactless testing system 100 moves a plurality of RF probes to target positions. In various embodiments, an RF control module 132 included in the contactless testing system 200 generates one or more commands that move one or more RF probe carriers 224 included in the contactless testing system 200 to target positions and/or target orientations. The positioning of the one or more RF probe carriers 224 enables a plurality of RF probes 226 to be proximate to contact pads 242 on the DUT 240 for capacitive coupling. The contact pads 242 correspond to a plurality of WUTs 544 that are to be tested in parallel.

At step 804, the contactless testing system verifies whether the one or more RF probe carriers 224 are at the target position and/or the target orientation. In various embodiments, the RF control module 132 acquires sensor data (e.g., image data, laser measurements, sonic data, mechanical data, magnetic data, etc.) to determine the position of the plurality RF probes 226 (e.g., 226(1)-226(4)) on the RF probe carrier 224 along the x, y, and z axes, as well as determine an orientation (e.g., tilt relative to a plane of the testing device 140 and/or the DUT 150) of the respective RF probes 226. The RF control module 132 can then use the location and orientation to verify whether a given RF probe 226 is at a probe distance 230 that is proximate to the target contact pad 242. When the RF control module 132 determines that each of the RF probes 226 is at the target position and/or the target orientation, the contactless testing system 200 proceeds to step 806. Otherwise, when the RF control module 132 determines that at least one RF probe 226 is not at the target position or orientation, the RF control module 132 returns to step 802, where the RF control module 132 can send one or more commands to the RF probe carrier 224 to adjust the position of the RF probe carrier 224 and/or the RF probe 226. In such instances, the RF control module 132 can iteratively perform steps 802-804 by processing data acquired by the probe card 220 and generate commands to adjust the RF probe carriers 224 and/or the RF probes 226 before completing verification.

At step 806, the contactless testing system drives the source probe to induce test RF signals into a plurality of wires under test (WUTs). In various embodiments, the RF control module 132 drives an RF tester 212 to generate a test RF signal f₁. The test RF signal f₁ transmits along a signal path through the probe card 220, optionally through the RF switch 222(1), the source RF probe carrier 224(1), and a source RF probe 226(1). Due to the coupling between the source RF probe 226(1) and a contact pad 512(1), the source RF probe 226(1) induces a current in a WUT 544(1) connected to the contact pad 512(1). The RF control module 132 performs parallel testing of multiple WUTs 544(1)-544(3) by driving the RF tester 212 to generate multiple test RF signals (e.g., test signals f₁-f₆). In such instances, the plurality of test RF signals includes a first set of test RF signals for the WUTs 544(1)-544(3), as well as one or more test RF signals for neighboring wires. In such instances, the additional test RF signals can be measured to identify potential shorts due to neighboring wires and/or interference.

At step 808, the contactless testing system detects one or more measurement RF signals. In various embodiments the receiving RF probe carrier 224(2) receives, via one or more couplings of receiving RF probes 226(5)-226(8) to one or more receiving contact pads 522, one or more measurement RF signals m. A given measurement RF signal m corresponds to a current in a given WUT 544. For example, when performing parallel testing of the plurality of WUTs 544(1)-544(3), the receiving probe carrier 224(2) includes a plurality receiving probes 226(5)-226(8) coupled to a plurality of receiving contact pads 522(1)-522(3). When the plurality of source probes 226(1)-226(3) induce a plurality of currents in the WUTs 544(1)-544(3) and neighboring wires 244, the receiving probe carrier 224(2) can measure a plurality measurement RF signals m₁-m₃ that correspond to the respective currents transmitted by the WUTs 544(1)-544(3).

At step 810, the contactless testing system transmits the measurement RF signals to a testing module. In various embodiments, the measurement RF signals m₁-m₃ detected by the receiving RF probe carrier 224(2) are transmitted via the probe card 220 and/or the RF tester 212 to the testing module 134. In some embodiments, the RF probe carrier 224(2) sends each of the measurement RF signals in parallel. Alternatively, in some embodiments, the RF probe carrier 224(2) and/or the RF switch 222(2) acts as a combiner and combines multiple measurement RF signals m₁-m₃ into a single signal. In such instances, the RF probe carrier 224(2) and/or the RF switch 222(2) transmits the combined measurement RF signal to the testing module 134.

At step 812, the contactless testing system generates test results for the plurality of WUTs based on the measurement RF signals. In various embodiments, the testing module 134 analyzes the received measurement RF signals m₁-m₃ to identify any failures associated with the WUTs 544(1)-544(3) and determines whether the DUT 240 is faulty. In some embodiments, the testing module performs step 812 after the contactless testing system 100 performed measurements for the entire DUT 240. For example, the testing module 134 identifies the DUT 240 as faulty upon identifying at least one failure condition associated with at least one of the WUTs 544(1)-544(3). Alternatively, in some embodiments, the testing module 134 can identify a potential failure condition for at least one of the WUTs 544(1)-544(3) and flag the analysis for further review. Additionally, or alternatively, the testing module 134 can deduce a cause for the failure, such as a spatial pattern to identify which of the WUTs 544(1)-544(3) failed, a strength indication to determine the number of full defects compared to resistive defects, and/or any differences in symmetry of results. Upon generating test results for WUTs 544(1)-544(3), the contactless testing system 200 can return to step 802 to move the RF probes 226 to test another group of WUTs 544.

In some embodiments, steps 802-812 are performed continually. In such instances, the testing module 134 can receive and/or analyze measurements while the RF probes 226 are moving. For example, the contactless testing system 200 can perform step 802 to move one or more RF probes 226 while completing one or more of steps 806, 808, 810, or 812. Alternatively, one or more of steps 802-812 can be performed stepwise. For example, the contactless testing system 200 can complete one or more of steps 806, 808, 810, or 812 before returning to step 802 to move one or more RF probe 226. Additionally, or alternatively, one or more of steps 802-812 can be optional steps performed by the contactless testing system 100. For example, the contactless testing system can forgo step 804 of verifying whether the probe carriers 224 are in a target position while the probe carriers 224 remain in motion.

In sum, the contactless testing system disclosed herein enables interface routes of interposers and silicon bridges to be tested and evaluated in parallel without requiring contact with any leads, contact pads, solder balls, or pins. The contactless testing system includes a plurality of RF probes that are configured to establish a capacitive coupling with a plurality of contact leads of a device under test, such as an interposer. During testing, a probe card connected to the RF probes responds to commands by moving the RF probes to desired locations and desired positions proximate to a plurality of target contact leads on the device under test. The probe card moves the RF probes along the x-axis, y-axis, and z-axis and can tilt the RF probes to modify orientations relative to the device under test. A given RF probe includes a cable that can be extended to change the distance between the distal end of the RF probe and the contact pad. Once at the target positions, source RF probes couples with a first plurality of contact pads and a receiving RF probe couples with a second plurality of contact pads, each without making contact. An RF tester generates a plurality test signals at one or more selected frequencies. The source RF probes induce a plurality of wires that are respectively connected to the first plurality of contact pads to transmit the respective test signals. The receiving RF probes measure a plurality of measurement RF signals from the second plurality of contact pads. The probe transmits the plurality of measurement RF signals to a testing module. The testing module analyzes the plurality of measurement RF signals and identifies any test failures. The testing module provides plurality of the measurement RF signals and the test results for evaluation of the device under test.

At least one technical advantage of the disclosed techniques relative to the prior art is that, with the disclosed techniques, interposers, silicon bridges, and other electronic equipment can be tested quickly and accurately using a parallel contactless approach without the need of bulky and costly imaging-based systems. In particular, the parallel contactless approach moves probes proximate to the DUT and performs parallel electrical tests that typically require sequential contact between a pair of contact points on the DUT and the testing system. In this manner, a testing system using the parallel contactless approach can acquire accurate results for multiple wires without damaging the DUT or introducing false measurements due to contact errors. The disclosed techniques also accurately identify faults, such as opens, shorts, and potential failures of neighboring wires, at greater speeds and at lower costs than conventional testing systems. Further, the disclosed techniques can identify functioning wires and faults with greater accuracy. These technical advantages provide one or more technological advancements over prior art approaches.
1. In various embodiments, a testing system comprises automated test equipment, and a probe card coupled to the automated test equipment, the probe card including a first plurality of probes, where the automated test equipment is configured to move the first plurality of probes proximate to a first plurality of contacts of a device under test (DUT), where each contact of the first plurality of contacts is connected to a wire of a plurality of wires, move a second plurality of probes proximate to a second plurality of contacts of the DUT, where each contact of the second plurality of contacts is connected to a wire of the plurality of wires, drive each probe of the first plurality of probes with one of a plurality of first RF signals to induce a plurality of second RF signals in the plurality of wires, where the first plurality of probes move relative to the DUT during the driving, measure, via the plurality of second probes, at least one RF signal of the plurality of second RF signals, where the second plurality of probes move relative to the DUT during the measuring, and generate a test result based on at least the one RF signal of the plurality of second RF signals.
2. The testing system of clause 1, where the automated test equipment is further configured to measure in parallel at least a subset of the plurality of second RF signals, where the test result is based at least on the subset of the plurality of second RF signals, and the test result is one of an open condition, a short condition, a resistive open condition, a resistive short condition, or a resonant frequency.
3. The testing system of clause 1 or 2, where the DUT comprises an interposer or a silicon bridge.
4. The testing system of any of clauses 1-3, further comprising a splitter that transmits a first RF signal of the plurality of first RF signals to at least two probes of the first plurality of probes.
5. The testing system of any of clauses 1-4, further comprising a combiner that combines at least two RF signals of the plurality of second RF signals into a combined RF signal, where the test result is based on at least the combined RF signal.
6. The testing system of any of clauses 1-5, where none of the first plurality of probes or the second plurality of probes contact the DUT.
7. The testing system of any of clauses 1-6, where the automated test equipment is configured to modify a probe distance of one of the plurality of first probes to change a signal path from a first signal path length to a second signal path length, and at least the one RF signal of the plurality of second RF signals includes a resonant frequency when recorded at the second signal path length.
8. The testing system of any of clauses 1-7, where at least one of the first plurality of probes or the second plurality of probes includes a probe that is configured to tilt relative to a plane of the DUT.
9. The testing system of any of clauses 1-8, where the automated test equipment is further configured to move the first plurality of probes proximate to a third plurality of contacts of the DUT while measuring the at least one RF signal of the plurality of second RF signals, where each contact of the third plurality of contacts is connected to a wire of a second plurality of wires.
10. The testing system of any of clauses 1-9, where the test result includes a strength indication associated with a first number of full defects and a second number of resistive defects.
11. In various embodiments, a computer-implemented method for testing an interposer or silicon bridge comprises moving, by automated test equipment, a first plurality of probes proximate to a first plurality of contacts of a device under test (DUT), where each contact of the first plurality of contacts is connected to a wire of a plurality of wires, moving, by the automated test equipment, a second plurality of probes proximate to a second plurality of contacts of the DUT, where each contact of the second plurality of contacts is connected to a wire of the plurality of wires, driving, by the automated test equipment, each probe of the first plurality of probes with one of a plurality of first RF signals to induce a plurality of second RF signals in the plurality of wires, where the first plurality of probes move relative to the DUT during the driving, measuring, by the automated test equipment via the plurality of second probes, at least one RF signal of the plurality of second RF signals, where the second plurality of probes move relative to the DUT during the measuring, and generating, by the automated test equipment, a test result based on at least the one RF signal of the plurality of second RF signals.
12. The computer-implemented method of clause 11, where the test result is one of an open condition, a short condition, a resistive open condition, a resistive short condition, or a resonant frequency.
13. The computer-implemented method of clause 11 or 12, further comprising measuring, by the automated test equipment at least a subset of the plurality of second RF signals in parallel.
14. The computer-implemented method of any of clauses 11-13, further comprising transmitting, by the automated testing equipment via a splitter, a first RF signal of the plurality of first RF signals to at least two probes of the first plurality of probes.
15. The computer-implemented method of any of clauses 11-14, further comprising causing, by the automated testing equipment, a combiner to combine at least two RF signals of the plurality of second RF signals into a combined RF signal, where the test result is based on at least the combined RF signal.
16. The computer-implemented method of any of clauses 11-15, where the test result includes a spatial pattern identifying one or more wires that failed.
17. The computer-implemented method of any of clauses 11-16, where none of first plurality of probes or the second plurality of probes contact the DUT.
18. The computer-implemented method of any of clauses 11-17, further comprising modifying, by the automated test equipment, a probe distance of one of the plurality of first probes to change a signal path from a first signal path length to a second signal path length, where at least the one RF signal of the plurality of second RF signals includes a resonant frequency when recorded at the second signal path length.
19. The computer-implemented method of any of clauses 11-18, further comprising moving the first plurality of probes proximate to a third plurality of contacts of the DUT while performing at least one of driving each probe of the first plurality of probes with one of a plurality of first RF signals, measuring the at least one RF signal of the plurality of second RF signals, or generating the test result, where each contact of the third plurality of contacts is connected to a wire of a second plurality of wires.
20. In various embodiments, one or more non-transitory computer-readable media store program instructions that, when executed by one or more processors, cause the one or more processors to perform a method comprising moving, by automated test equipment, a first plurality of probes proximate to a first plurality of contacts of a device under test (DUT), where each contact of the first plurality of contacts is connected to a wire of a plurality of wires, moving, by the automated test equipment, a second plurality of probes proximate to a second plurality of contacts of the DUT, where each contact of the second plurality of contacts is connected to a wire of the plurality of wires, driving, by the automated test equipment, each probe of the first plurality of probes with one of a plurality of first RF signals to induce a plurality of second RF signals in the plurality of wires, where the first plurality of probes move relative to the DUT during the driving, measuring, by the automated test equipment via the plurality of second probes, at least one RF signal of the plurality of second RF signals, where the second plurality of probes move relative to the DUT during the measuring, and generating, by the automated test equipment, a test result based on at least the one RF signal of the plurality of second RF signals.

Any and all combinations of any of the claim elements recited in any of the claims and/or any elements described in this application, in any fashion, fall within the contemplated scope of the present invention and protection.

The descriptions of the various embodiments have been presented for purposes of illustration, but are not intended to be exhaustive or limited to the embodiments disclosed. Many modifications and variations will be apparent to those of ordinary skill in the art without departing from the scope and spirit of the described embodiments.

Aspects of the present embodiments can be embodied as a system, method or computer program product. Accordingly, aspects of the present disclosure can take the form of an entirely hardware embodiment, an entirely software embodiment (including firmware, resident software, micro-code, etc.) or an embodiment combining software and hardware aspects that can all generally be referred to herein as a “module,” a “system,” or a “computer.” In addition, any hardware and/or software technique, process, function, component, engine, module, or system described in the present disclosure can be implemented as a circuit or set of circuits. Furthermore, aspects of the present disclosure can take the form of a computer program product embodied in one or more computer readable medium(s) having computer readable program code embodied thereon.

Any combination of one or more computer readable medium(s) can be utilized. The computer readable medium can be a computer readable signal medium or a computer readable storage medium. A computer readable storage medium can be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium can be any tangible medium that can contain, or store a program for use by or in connection with an instruction execution system, apparatus, or device.

Aspects of the present disclosure are described above with reference to flowchart illustrations and/or block diagrams of methods, apparatus (systems) and computer program products according to embodiments of the disclosure. It will be understood that each block of the flowchart illustrations and/or block diagrams, and combinations of blocks in the flowchart illustrations and/or block diagrams, can be implemented by computer program instructions. These computer program instructions can be provided to a processor of a general purpose computer, special purpose computer, or other programmable data processing apparatus to produce a machine. The instructions, when executed via the processor of the computer or other programmable data processing apparatus, enable the implementation of the functions/acts specified in the flowchart and/or block diagram block or blocks. Such processors can be, without limitation, general purpose processors, special-purpose processors, application-specific processors, or field-programmable gate arrays.

The flowchart and block diagrams in the figures illustrate the architecture, functionality, and operation of possible implementations of systems, methods and computer program products according to various embodiments of the present disclosure. In this regard, each block in the flowchart or block diagrams can represent a module, segment, or portion of code, which comprises one or more executable instructions for implementing the specified logical function(s). It should also be noted that, in some alternative implementations, the functions noted in the block can occur out of the order noted in the figures. For example, two blocks shown in succession may, in fact, be executed substantially concurrently, or the blocks can sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

While the preceding is directed to embodiments of the present disclosure, other and further embodiments of the disclosure can be devised without departing from the basic scope thereof, and the scope thereof is determined by the claims that follow.

What is claimed is:

1. A testing system comprising:
automated test equipment; and
a probe card coupled to the automated test equipment, the probe card including a first plurality of probes;
wherein the automated test equipment is configured to:
move the first plurality of probes proximate to a first plurality of contacts of a device under test (DUT), wherein each contact of the first plurality of contacts is connected to a wire of a plurality of wires;
move a second plurality of probes proximate to a second plurality of contacts of the DUT, wherein each contact of the second plurality of contacts is connected to a wire of the plurality of wires;
drive each probe of the first plurality of probes with one of a plurality of first RF signals to induce a plurality of second RF signals in the plurality of wires, wherein the first plurality of probes move relative to the DUT during the driving;
measure, via the plurality of second probes, at least one RF signal of the plurality of second RF signals, wherein the second plurality of probes move relative to the DUT during the measuring; and
generate a test result based on at least the one RF signal of the plurality of second RF signals.

2. The testing system of claim 1, wherein the automated test equipment is further configured to measure in parallel at least a subset of the plurality of second RF signals, wherein:
the test result is based at least on the subset of the plurality of second RF signals, and
the test result is one of an open condition, a short condition, a resistive open condition, a resistive short condition, or a resonant frequency.

3. The testing system of claim 1, wherein the DUT comprises an interposer or a silicon bridge.

4. The testing system of claim 1, further comprising a splitter that transmits a first RF signal of the plurality of first RF signals to at least two probes of the first plurality of probes.

5. The testing system of claim 1, further comprising a combiner that combines at least two RF signals of the plurality of second RF signals into a combined RF signal, wherein the test result is based on at least the combined RF signal.

6. The testing system of claim 1, wherein none of the first plurality of probes or the second plurality of probes contact the DUT.

7. The testing system of claim 1, wherein:
the automated test equipment is configured to modify a probe distance of one of the first plurality of probes to change a signal path from a first signal path length to a second signal path length; and
at least the one RF signal of the plurality of second RF signals includes a resonant frequency when recorded at the second signal path length.

8. The testing system of claim 1, wherein at least one of the first plurality of probes or the second plurality of probes includes a probe that is configured to tilt relative to a plane of the DUT.

9. The testing system of claim 1, wherein the automated test equipment is further configured to move the first plurality of probes proximate to a third plurality of contacts of the DUT while measuring the at least one RF signal of the plurality of second RF signals, wherein each contact of the third plurality of contacts is connected to a wire of a second plurality of wires.

10. The testing system of claim 1, wherein the test result includes a strength indication associated with a first number of full defects and a second number of resistive defects.

11. A computer-implemented method for testing an interposer or silicon bridge, the method comprising:
moving, by automated test equipment, a first plurality of probes proximate to a first plurality of contacts of a device under test (DUT), wherein each contact of the first plurality of contacts is connected to a wire of a plurality of wires;
moving, by the automated test equipment, a second plurality of probes proximate to a second plurality of contacts of the DUT, wherein each contact of the second plurality of contacts is connected to a wire of the plurality of wires;
driving, by the automated test equipment, each probe of the first plurality of probes with one of a plurality of first RF signals to induce a plurality of second RF signals in the plurality of wires, wherein the first plurality of probes move relative to the DUT during the driving;
measuring, by the automated test equipment via the plurality of second probes, at least one RF signal of the plurality of second RF signals, wherein the second plurality of probes move relative to the DUT during the measuring; and
generating, by the automated test equipment, a test result based on at least the one RF signal of the plurality of second RF signals.

12. The computer-implemented method of claim 11, wherein the test result is one of an open condition, a short condition, a resistive open condition, a resistive short condition, or a resonant frequency.

13. The computer-implemented method of claim 11, further comprising measuring, by the automated test equipment at least a subset of the plurality of second RF signals in parallel.

14. The computer-implemented method of claim 11, further comprising transmitting, by the automated testing equipment via a splitter, a first RF signal of the plurality of first RF signals to at least two probes of the first plurality of probes.

15. The computer-implemented method of claim 11, further comprising causing, by the automated testing equipment, a combiner to combine at least two RF signals of the plurality of second RF signals into a combined RF signal, wherein the test result is based on at least the combined RF signal.

16. The computer-implemented method of claim 11, wherein the test result includes a spatial pattern identifying one or more wires that failed.

17. The computer-implemented method of claim 11, wherein none of first plurality of probes or the second plurality of probes contact the DUT.

18. The computer-implemented method of claim 11, further comprising:
modifying, by the automated test equipment, a probe distance of one of the plurality of first probes to change a signal path from a first signal path length to a second signal path length,
wherein at least the one RF signal of the plurality of second RF signals includes a resonant frequency when recorded at the second signal path length.

19. The computer-implemented method of claim 11, further comprising:
moving the first plurality of probes proximate to a third plurality of contacts of the DUT while performing at least one of:
driving each probe of the first plurality of probes with one of a plurality of first RF signals,
measuring the at least one RF signal of the plurality of second RF signals, or
generating the test result,
wherein each contact of the third plurality of contacts is connected to a wire of a second plurality of wires.

20. One or more non-transitory computer-readable media storing program instructions that, when executed by one or more processors, cause the one or more processors to perform a method comprising:
moving, by automated test equipment, a first plurality of probes proximate to a first plurality of contacts of a device under test (DUT), wherein each contact of the first plurality of contacts is connected to a wire of a plurality of wires;
moving, by the automated test equipment, a second plurality of probes proximate to a second plurality of contacts of the DUT, wherein each contact of the second plurality of contacts is connected to a wire of the plurality of wires;
driving, by the automated test equipment, each probe of the first plurality of probes with one of a plurality of first RF signals to induce a plurality of second RF signals in the plurality of wires, wherein the first plurality of probes move relative to the DUT during the driving;
measuring, by the automated test equipment via the plurality of second probes, at least one RF signal of the plurality of second RF signals, wherein the second plurality of probes move relative to the DUT during the measuring; and
generating, by the automated test equipment, a test result based on at least the one RF signal of the plurality of second RF signals.
